(19) United States
(12) Patent Application Publication
(10) Pub. No.: US 2014/0134849 A1
(43) Pub. Date: May 15, 2014

(54) Combinatorial Site Isolated Plasma Assisted Deposition

(71) Applicant: INTERMOLECULAR INC., San Jose, CA (US)

(72) Inventors: Sandip Niyogi, San Jose, CA (US); Owen Ho Yin Fong, San Jose, CA (US); Sunil Shanker, Santa Clara, CA (US); ShouQian Shao, Fremont, CA (US); Jingang Su, Cupertino, CA (US); J. Watanabe, San Jose, CA (US); Wenxian Zhu, E. Palo Alto, CA (US)

(73) Assignee: INTERMOLECULAR INC., San Jose, CA (US)

(21) Appl. No.: 13/672,840

(22) Filed: Nov. 9, 2012

(51) Int. Cl. C23C 16/458; H01L 21/02

(52) U.S. Cl. CPC C23C 16/458; H01L 21/0234
USPC 438/761; 118/723 R

(57) ABSTRACT

An apparatus that includes a base, a sidewall extending from the base, and a lid disposed over a top of the sidewall is provided. A plasma generating source extends through a surface of the lid. A rotatable substrate support is disposed within the chamber above a surface of the base, the rotatable substrate support operable to vertically translate from the base to the lid. A first fluid inlet extends into a first surface of the sidewall and a second fluid inlet extends into a second surface of the sidewall. The plasma generating source provides a plasma activated species to a region of a surface of a substrate supported on the rotatable substrate support and a fluid delivered proximate to the region from one of the first or the second fluid inlet interacts with the plasma activated species to deposit a layer of material over the region.

### BACKGROUND

Combinatorial processing may refer to various techniques used to vary characteristics of the processes applied to multiple regions of a substrate in serial, parallel or parallel-serial fashion. Combinatorial processing may be used to test and compare multiple and various processing techniques. The processing techniques may be validated, and those techniques that are useful may be applied to, for example, different substrates or full-substrate processing.

In a combinatorial processing system, films may be deposited through vapor deposition on a particular localized area on a wafer or substrate. However, when performing site isolated spot deposition in the combinatorial processing system, as well as conventional processing systems, the plasma source and film source are combined. The coupling or combination of the plasma source and the film source make it difficult for chemical vapor deposition (CVD) processes to be used for thin film deposition, for both full wafer and combinatorial processing. In addition, with regard to plasma assisted atomic layer deposition (PEALD), defects and vacancies caused by incomplete oxidation of the metal source are difficult to control. Combinatorial processing techniques look to optimize process variables in order to provide a robust process.

It is within this context that the embodiments arise.

### BRIEF DESCRIPTION OF DRAWINGS

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration.

FIG. 3 is a simplified schematic diagram illustrating an integrated high productivity combinatorial (HPC) system in accordance with some embodiments of the invention

FIG. 4 is a simplified schematic diagram illustrating a deposition chamber configured to perform combinatorial processing in accordance with some embodiments of the invention.

FIGS. 5A-D are schematic diagrams illustrating a combinatorial processing method utilizing the processing chamber in accordance with some embodiments of the invention.

FIG. 6 is a flowchart diagram illustrating the method operations for depositing material on a substrate in accordance with some embodiments.

### SUMMARY

According to some embodiments of the invention, an apparatus for combinatorial deposition processing is provided. The apparatus includes a base, a sidewall extending from the base, and a lid disposed over a top of the sidewall. A plasma generating source extends through a surface of the lid. A rotatable substrate support is disposed within the chamber above a surface of the base, the rotatable substrate support is operable to vertically translate from the base to the lid. A first fluid inlet extends into a first surface of the sidewall and a second fluid inlet extends into a second surface of the sidewall. The plasma generating source provides a plasma activated species to a region of a surface of a substrate supported on the rotatable substrate support and a fluid delivered proximate to the region from one of the first or the second fluid inlet interacts with the plasma activated species to deposit a layer of material over the region. It should be appreciated that a plasma activated species refers to the reactive atomic and molecular radicals created by the plasma from the precursor gas.

In some embodiments, a method for depositing material is provided. The method includes activating a plasma over a first region of a surface of a substrate, where the plasma is activated from a plasma source having an inlet surface opposing the surface of the substrate. The method includes flowing a first film source fluid in a plane substantially parallel to the surface of the substrate, the first film source fluid interacting with the plasma proximate to the first region and depositing a first film composed of components of the first film source fluid on the first region.

Various other objects, features, and advantages of the invention will be apparent through the detailed description of the preferred embodiments and the drawings attached hereto.

It is also to be understood that both the foregoing general description and the following detailed description are exemplary and not restrictive of the scope of the invention.

### DETAILED DESCRIPTION

The embodiments described herein provide a method and apparatus related to deposition processing. It will be obvious, however, to one skilled in the art, that the present invention may be practiced without some or all of these specific details. In other instances, well known process operations have not been described in detail in order not to unnecessarily obscure the present invention.

In the drawings, like reference numerals appearing in different drawings represent similar or same components and perform similar or same functions, unless specifically noted otherwise in the description. Furthermore, as would be appreciated by those skilled in the art, according to common practice, the various features of the drawings discussed herein are not necessarily drawn to scale, and that dimensions of various features, structures, or characteristics of the drawings may be expanded or reduced to more clearly illustrate various implementations of the invention described herein. Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

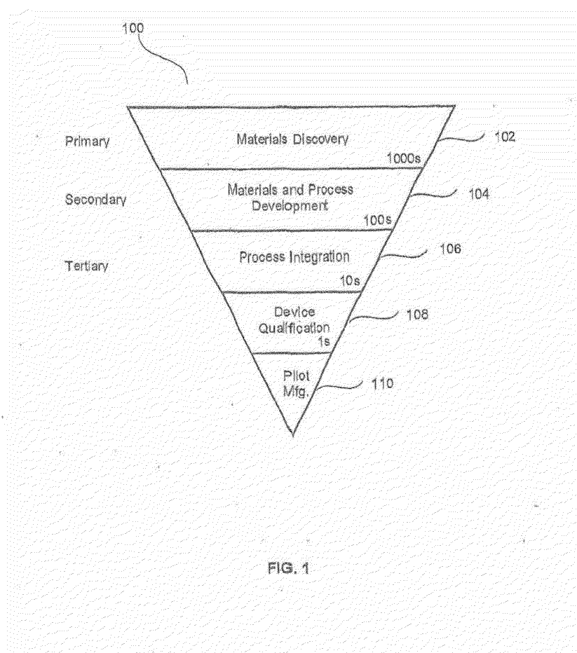

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

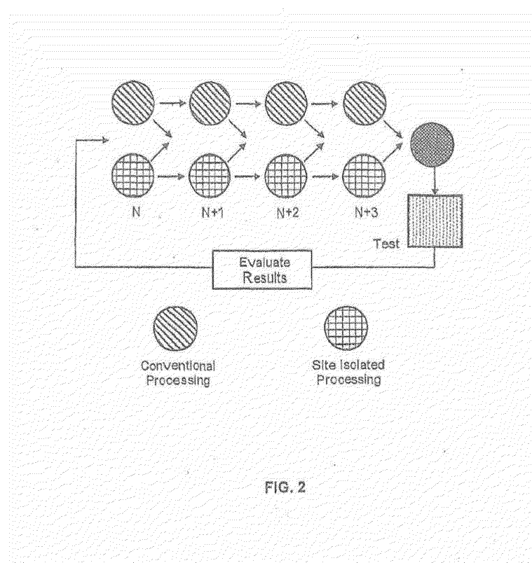

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

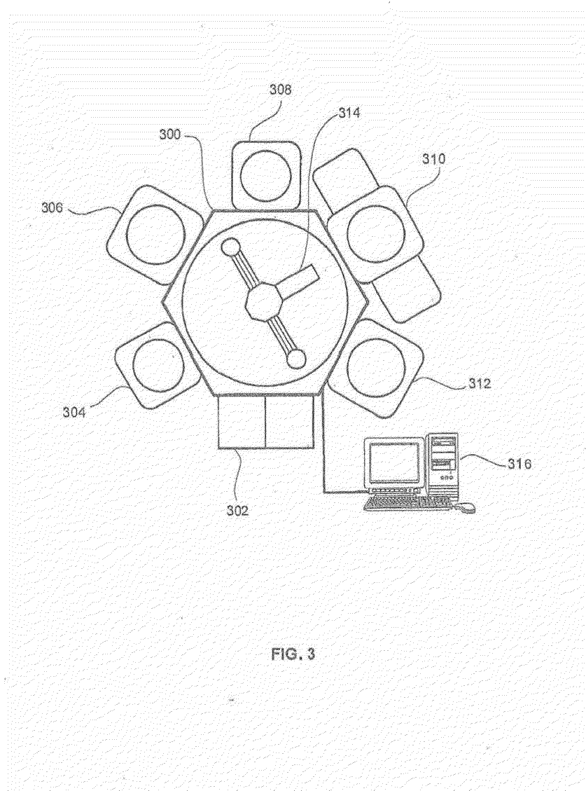

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in US application Ser. Nos. 11/672,478 and 11/672,473. With HPC system, a plurality of methods may be employed to deposit material upon a substrate employing combinatorial processes.

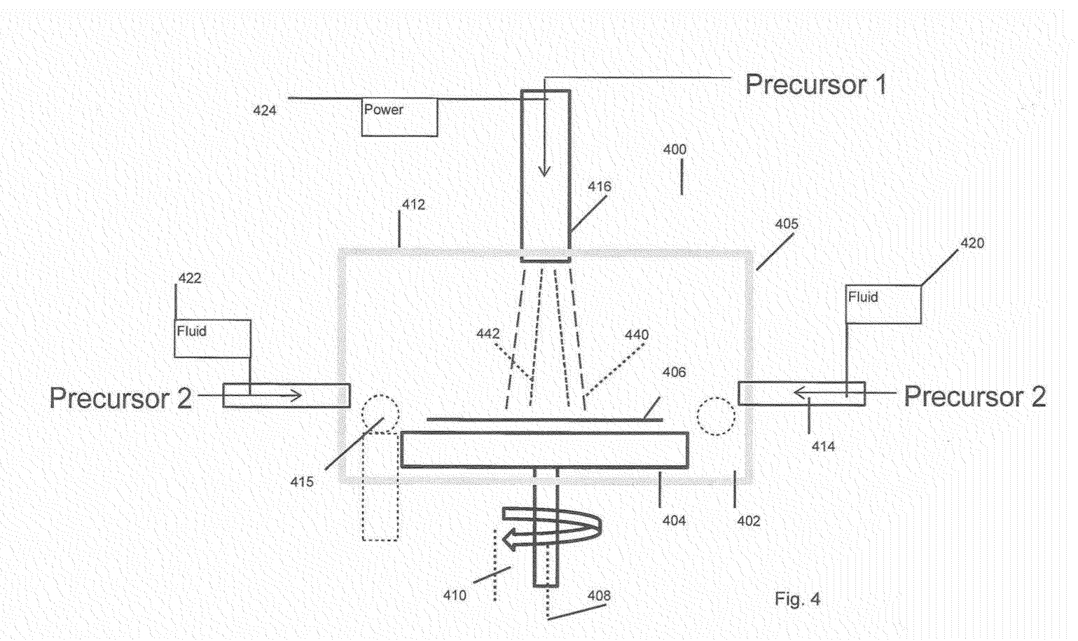

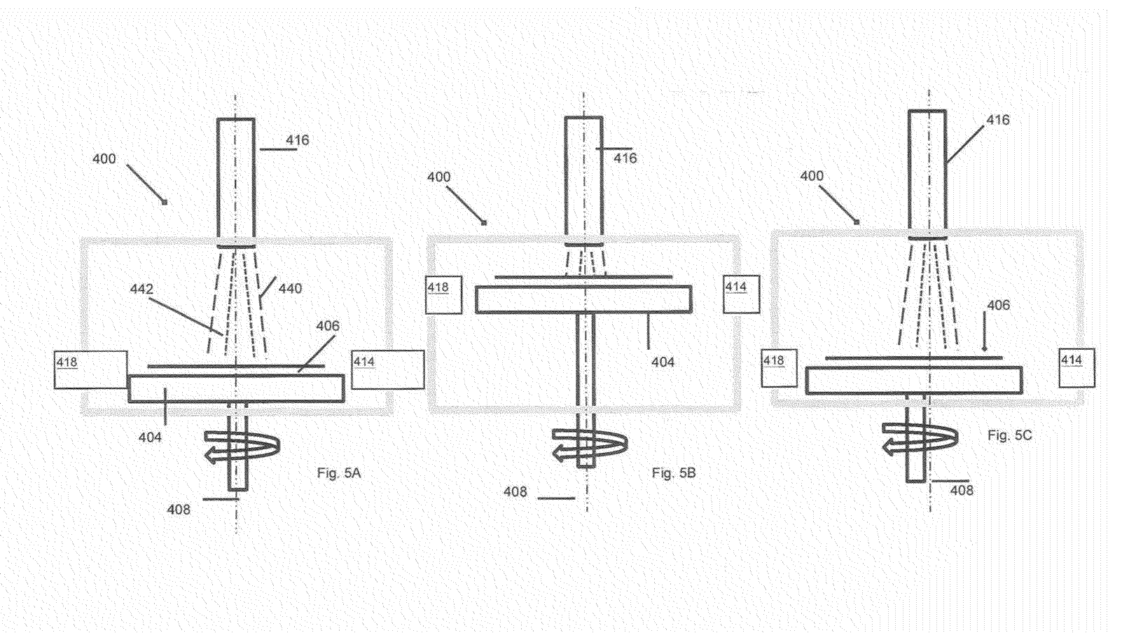

FIG. 4 is a simplified schematic diagram illustrating a deposition chamber configured to perform combinatorial processing in accordance with some embodiments of the invention. Processing chamber 400 includes substrate support 404 which is configured to hold a substrate 406 disposed thereon and can be any known substrate support, including but not limited to a vacuum chuck, electrostatic chuck or other known mechanisms. Substrate support 404 is capable of both rotating around its own central axis 408 (referred to as “rotation” axis), and rotating around a second axis 410 (referred to as “revolution” axis). Such dual rotary substrate support is central to combinatorial processing using site-isolated mechanisms. Other substrate supports, such as an XY table, can also be used for site-isolated deposition. In addition, substrate support 404 may move in a vertical direction, i.e., away from or towards lid 412. It should be appreciated that the rotation and movement in the vertical direction may be achieved through known drive mechanisms which include magnetic drives, linear drives, worm screws, lead screws, a differentially pumped rotary feed through drive, etc. Power source 426 provides power to plasma generation source 416. It should be appreciated that power source 426 may output a direct current (DC) power supply, a pulsed DC power supply, or a radio frequency (RF) power supply.

Substrate 406 may be a conventional round 200 mm, 300 mm substrate, or any other larger or smaller substrate/wafer size. In some embodiments, substrate 406 may be a square, rectangular, or other shaped substrate. One skilled in the art will appreciate that substrate 406 may be a blanket substrate, a coupon (e.g., partial wafer), or even a patterned substrate having predefined regions. In some embodiments, substrate 406 may have regions defined through the processing described herein. The term “region” is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

Chamber 400 in FIG. 4 includes lid 412, where plasma generation source 416 extends through a portion of the lid. Fluid inlets 414 and 418 extend into chamber 400 through sidewalls 405 or a base of chamber 400. Fluid inlet 414 is in fluid communication with fluid source 420, while fluid inlet 418 is in fluid communication with fluid source 422. Fluid inlets 414 and 418 may be in fluid communication with the same fluid source in some embodiments or different fluid sources in other embodiments. It should be appreciated that fluid inlets 414 and 418 may extend around a surface of substrate 406 so that a perimeter of substrate 406 is encompassed by fluid inlets 414 and 418. In some embodiments, fluid inlets 414 and 418 are configured as ring portions surrounding substrate 406. The flow of the fluid from fluid inlets 414 and 418 converges proximate to the region where the plasma activated species is focused, thereby depositing a layer of material at the specific region. In some embodiments, fluid inlets 414 and 418 are movable to vertically translate along with substrate support 404 so that each fluid inlet remains proximate to an edge of substrate 406. For example, the ring portions may be coupled to an appropriate drive such as a worm gear, linear drive, etc., so that the fluid inlets 414 and 418 track the movement of the substrate and substrate support. Plasma generation source 416 is operable to provide a plasma activated species proximate to a surface of substrate 406. The plasma activated species provided by plasma generation source 416 has a non-reactive outer portion 440 surrounding a reactive inner portion 442 in accordance with some embodiments. It should be further appreciated that plasma generation source 416 may be a commercially available inductively coupled radio frequency (RF) plasma generation source. It should be appreciated that a plasma activated species refers to the reactive atomic and molecular radicals converted from the precursor gas through interaction with the plasma. It should be further appreciated that the plasma also consists of electrons and ions.

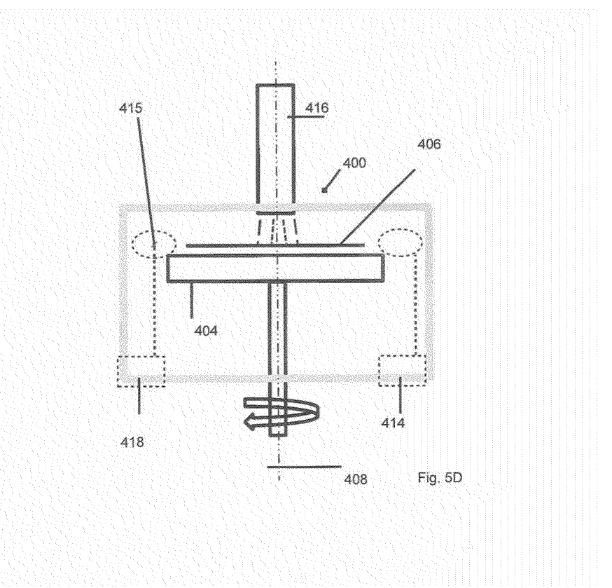

The embodiments illustrated in FIG. 4 provide for independent control of the plasma and the feedstock of the film to be deposited. Thus, the plasma activated species are provided by plasma generation source 416 located at the top of chamber 400, while the film feedstock is delivered through the chamber base to a ring disposed around the wafer surface. Alternatively, the film feedstock may be delivered through the bottom of the chamber to distribution ring 415 above or proximate to the substrate surface. In some embodiments, distribution ring 415 is coupled to substrate support 404 so that the ring vertically translates with the substrate support. It should be appreciated that the feedstock interacts with the plasma proximate to a surface of substrate 406 so that site isolated processing may be performed on different regions of substrate 406. As illustrated below with reference to FIGS. 5A through D, the size for each region deposited on a surface of substrate 406 may be determined by a distance between the surface of substrate 406 and an outlet of plasma generation source 416. It should be further appreciated that chamber 400 may be a vapor deposition chamber that includes chemical vapor deposition chambers and atomic layer deposition chambers. In some embodiments, a plasma provided through plasma generation source 416 includes a hydrogen, helium, or argon based plasma referred to as a first precursor. The film feedstock provided by fluid inlets 414 and 418 may be any suitable feedstock for the desired deposition layer and may be referred to as a second precursor. Thus, for some embodiments described herein, the first precursor carries the plasma activated species and activates the second precursor proximate to the substrate surface at a specific site or region. In some embodiments, the film feedstock may be methane (CH₄) so that an amorphous carbon layer is deposited on the region of the surface of substrate 406. With regard to an atomic layer deposition chamber (ALD), a pulsed exposure to oxygen radicals generated when oxygen gas is precursor 1, can be utilized to complete the oxidation of the metal source to avoid defects and vacancies in ALD films. In some embodiments, in order to generate a profile of nitrogen and oxygen in an ALD deposited TiN film, the ALD layer can be exposed to a N₂/O₂ plasma at regular intervals during film deposition.

FIGS. 5A-D are cross sectional schematic diagrams illustrating a combinatorial processing method utilizing the processing chamber in accordance with some embodiments of the invention. In FIG. 5A, substrate 406 is positioned at a first distance from an outlet of plasma generation source 416. The diameter of reactive area 442 of the first precursor fluid proximate to a surface of substrate 406 is determined by this first distance. Fluid inlets 418 and 414 provide a second precursor proximate to the surface of the substrate 406 where the second precursor may be different than the first precursor or the same as the first precursor.

Moving to FIG. 5B, the substrate support 404 is raised so that the distance between a surface of substrate 406 and an outlet of plasma generation source 416 has been decreased. The decrease in the distance leads to a decrease in a diameter of a region deposited on a surface of substrate 406. The change in the area of the region where the plasma activated species is defined may be referred to as a “flashlight effect” in some embodiments. As mentioned above, fluid inlets 418 and 414 may be coupled to or integrated with substrate support 404. Fluid inlets 418 and 414 may be configured as arcs or ring portions that are proximate to the edge of substrate 406 in some embodiments. In other embodiments, fluid inlets 414 and 418 may be configured as a monolithic ring surrounding an entirety of the periphery of substrate 406. Thus, it should be appreciated that the configuration on the fluid inlets may be any suitable configuration that provides the respective fluid to reactive area 442 so that material can be deposited on the surface of substrate 406.

In FIG. 5C substrate support 404 has been vertically translated away from an outlet of plasma generation source 416. The location for reactive area 442 changes due to the rotation of substrate support 404 around a second axis, i.e., the revolution axis. Thus, FIG. 5B illustrates the deposition of different spot sizes disposed over each other while FIG. 5C illustrates the deposition of different spot sizes on different isolated regios of substrate 406. Accordingly, the embodiments described herein enable further flexibility for the combinatorial processing described above with regard to FIGS. 1 and 2. It should be appreciated that the drives for the rotational, vertical and lateral movement of substrate support 404 may be any known drives including worm gear, lead screw, magnetically coupled, etc.

FIG. 5D illustrates fluid inlets 414 and 418 entering though a base of the chamber and distribution ring 415 coupled or integrated into substrate support 404. Distribution ring 415 is proximate to a surface of substrate 406. The delivery tube coupling fluid inlets 414 and 418 to distribution ring 415 may telescopically expand in some embodiments in order to vertically translate with substrate support 404. In addition, while distribution ring 415 may be a continuous ring disposed around the periphery of substrate 406, this is not meant to be limiting. For example, distribution ring 415 may be configured as a plurality of ring portions or arcs which may be coupled to the same fluid supply, dedicated fluid supplies for each ring portion, or some combination. In addition, each fluid supply may supply the same or different fluids. Thus, through the embodiments described herein multiple regions of substrate 406 may be deposited under varying conditions with different materials. In addition, each of the deposited regions may have different processing parameters and/or materials associated therewith, as well as different regions sizes, e.g., diameters. It should be appreciated, that in some embodiments the power delivered to plasma generating source 416 may be modified between the different regions deposited. Accordingly, the embodiments enable additional combinatorial processing combinations in order to evaluate multiple processes, process parameters, and materials in an efficient manner.

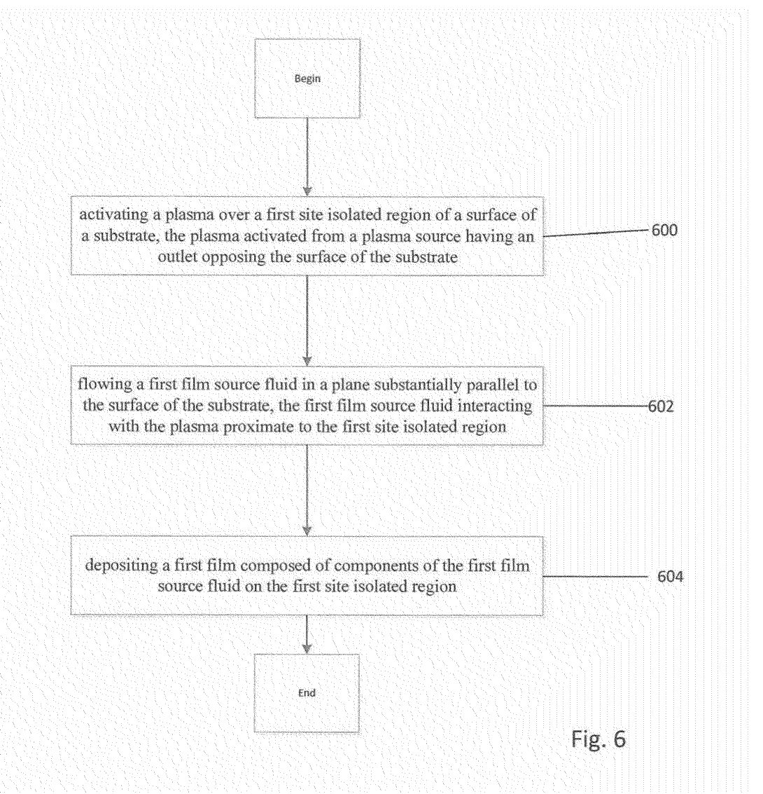

FIG. 6 is a flowchart diagram illustrating the method operations for depositing material on a substrate in accordance with some embodiments. FIG. 6 initiates with operation 600 where a plasma is activated over a first site isolated region of a surface of a substrate, the plasma activated from a plasma source having an outlet opposing the surface of the substrate. As illustrated in FIGS. 4-5D the plasma may originate from an inductively coupled RF plasma generation source in some embodiments. The method then advances to operation 602 where a first film source fluid flows in a plane substantially parallel to the surface of the substrate. The first film source fluid interacts with the plasma proximate to the first site isolated region. The film source fluid may be provided through a distribution ring as described above with reference to FIGS. 4-5D. The method then advances to operation 604 where a first film composed of components of the first film source fluid is deposited on the first site isolated region. It should be appreciated that multiple other site isolated regions may be deposited by rotating the substrate and repeating the above mentioned operations. In some embodiments the size or diameter of the deposited region may be varied by adjusting a distance between the surface of the substrate and the outlet of the plasma source.

Implementations of the invention may be described as including a particular feature, structure, or characteristic, but every aspect or implementation may not necessarily include the particular feature, structure, or characteristic. Further, when a particular feature, structure, or characteristic is described in connection with an aspect or implementation, it will be understood that such feature, structure, or characteristic may be included in connection with other implementations, whether or not explicitly described. Thus, various changes and modifications may be made to the provided description without departing from the scope or spirit of the invention. As such, the specification and drawings should be regarded as exemplary only, and the scope of the invention to be determined solely by the appended claims.

What is claimed is:

1. A processing chamber, comprising:
a base;
a sidewall extending from the base;
a lid disposed over a top of the sidewall;
a plasma generating source extending through a surface of the lid;
a rotatable substrate support disposed within the chamber above a surface of the base, the rotatable substrate support operable to vertically translate from the base to the lid;
a first fluid inlet extending through the base; and
a second fluid inlet extending through the base,
wherein the plasma generating source provides a plasma activated species to a region of a surface of a substrate supported on the rotatable substrate support and wherein a fluid delivered proximate to the region from one of the first or the second fluid inlet interacts with the plasma activated species to deposit a layer of material over the region.

2. The processing chamber of claim 1, wherein a size of the region is determined by a distance from an outlet of the plasma generating source to a surface of the substrate.

3. The processing chamber of claim 1, wherein the first fluid inlet and the second fluid inlet are operable to vertically translate along with the rotatable substrate support.

4. The processing chamber of claim 1, wherein the first fluid inlet extends around a first perimeter portion of the rotatable substrate support and wherein the second fluid inlet extends around a second perimeter portion of the rotatable substrate support.

5. The processing chamber of claim 1, wherein the rotatable substrate support is operable to rotate around multiple axes.

6. The processing chamber of claim 5, wherein the plasma activated species is isolated from a source of the material for the layer.

7. The processing chamber of claim 5, wherein the substrate is processed combinatorially with multiple site isolated regions defined on the surface of the substrate.

8. The processing chamber of claim 1, wherein the plasma activated species is one of hydrogen, nitrogen, argon, oxygen, ammonia, nitrogen trifluoride, helium or a combination of these gases.

9. The processing chamber of claim 8, wherein the fluid delivered proximate to the region deposits an amorphous carbon film when interacting with the plasma activated species.

10. The processing chamber of claim 1, wherein the processing chamber is a atomic layer deposition chamber.

11. A method for depositing material, comprising:
activating a plasma over a first site isolated region of a surface of a substrate, the plasma activated from a plasma source having an outlet opposing the surface of the substrate;
flowing a first film source fluid in a plane substantially parallel to the surface of the substrate, the first film source fluid interacting with the plasma proximate to the first site isolated region; and
depositing a first film composed of components of the first film source fluid on the first site isolated region.

12. The method of claim 11, further comprising:
rotating the substrate upon completion of the depositing;
activating the plasma over a second site isolated region of the surface of the substrate, the plasma activated from the plasma source;
flowing the first film source fluid in the plane substantially parallel to the surface of the substrate, the first film source fluid interacting with the plasma proximate to the second site isolated region; and
depositing the first film composed of components of the film source fluid on the second site isolated region.

13. The method of claim 12, wherein a power supplied to the plasma source for the plasma activated over the first region is different than a power supplied to the plasma source for the plasma activated over the second region.

14. The method of claim 11, further comprising:
rotating the substrate upon completion of the depositing;
activating the plasma over a third site isolated region of the surface of the substrate, the plasma activated from the plasma source;
flowing a second film source fluid in the plane substantially parallel to the surface of the substrate, the second film source fluid interacting with the plasma proximate to the third site isolated region; and
depositing a second film composed of components of the second film source fluid on the third site isolated region.

15. The method of claim 11, wherein the first film is an amorphous carbon film.

16. The method of claim 12, further comprising:
adjusting a distance between the surface of the substrate and the outlet of the plasma source after the rotating.

17. The method of claim 16, wherein an area of the second site isolated region is determined by the distance.

18. The method of claim 12, wherein the rotating includes rotating the substrate around multiple axes.

19. The method of claim 11, wherein an outlet for a source of the first film source is located around a perimeter of the substrate.

20. The method of claim 11, wherein the plasma is one of hydrogen, nitrogen, argon, oxygen, ammonia, nitrogen trifluoride, helium or a combination of these gases.
